(19) United States
(12) Patent Application Publication
(10) Pub. No.: US 2022/0042937 A1
(43) Pub. Date: Feb. 10, 2022

(54) METHOD AND SYSTEM FOR DETECTING AND CONTROLLING LONG-RANGE QUANTUM COHERENCE OF MOLECULAR INTERACTIONS

(71) Applicant: Sophyics Technology, LLC., McLean, VA (US)

(72) Inventors: Xindong WANG, Dayton, MD (US); Qiang FU, McLean, VA (US)

(73) Assignee: Sophyics Technology, LLC.

(21) Appl. No.: 17/375,802

(22) Filed: Jul. 14, 2021

Related U.S. Application Data
(60) Provisional application No. 63/060,833, filed on Aug. 4, 2020.

(51) Int. Cl. G01N 24/00

(52) U.S. Cl. CPC G01N 24/00

(57) ABSTRACT

The present disclosure provides a method and system for detecting and controlling the long-range quantum coherence of molecular interactions, e.g., hydrogen bonds, with an electrical current or electromagnetic field, e.g., in a low end of radio frequency range at room temperature. The resonant frequencies of molecular interactions such as hydrogen bonds may be detected and the long-range quantum coherence of the molecular interactions such as hydrogen bonds may be controlled with electrical current or electromagnetic fields.

### CROSS-REFERENCE TO RELATED APPLICATIONS

This application claims the benefit of priority to U.S. Provisional Application No. 63/060,833, filed on Aug. 4, 2020, the entire contents of which are incorporated herein by reference.

### TECHNICAL FIELD

This disclosure relates generally to a method and system for detecting and controlling the long-range quantum coherence of molecular interactions, e.g., hydrogen bonds, with an electrical current or electromagnetic field, e.g., in a low end of radio frequency range at room temperature. The resonant frequencies of molecular interactions such as hydrogen bonds may be detected and the long-range quantum coherence of the molecular interactions such as hydrogen bonds may be controlled with electrical current or electromagnetic fields.

### TECHNICAL BACKGROUND

An electric neutral molecule, such as a large biomolecule, in a liquid water environment contains local bonding sites that exchange charged particles. In quantum mechanics, the exchange processes can be described by the following coupling terms between the biomolecule and its liquid water environment, using hydrogen bonding as an example:

ĥ_{coupling}=c\hat{p}ₘ^{†}\hat{p}_{E}+c*\hat{p}_{E}^{†}\hat{p}ₘ, (1)

where \hat{p}ₘ^{†}\hat{p}_{E} denotes the process where a proton leaves the water environment (E) and is absorbed by the biomolecule (m), and its Hermitian conjugate \hat{p}_{E}^{†}\hat{p}ₘ denotes the reversed process (the proton leaving the molecule and back into the water environment). This coupling term ĥ_{coupling}, when treated quantum mechanically, creates an effective local Hamiltonian which, in its simplest 2-level form, can be represented by:

$${\hat{h}}_{eff} = ( \begin{matrix}{E}_{1} & Δ {e}^{i θ} \\ Δ {e}^{- i θ} & {E}_{2}\end{matrix} ) , \qquad ( 2 )$$

where E₁ is the local energy that corresponds to the local state that is charge neutral and E₂ denotes the higher energy state where the charge neutral is broken due to exchange of proton with water.

The effective Hamiltonian can be viewed as the simplest quantum mechanical model for Hydrogen bonding where the two eigenstates of the combined local system and water, form a quantum bi-level system and the relative phase between the two diagonal quantum states is referred herein as the off-diagonal quantum moments. Using amino acids as an example, the above model is further illustrated.

Amino acids generally exist in two forms of molecular structure in a water solution, the neutral molecular form and the Zwitterion form. The two forms of an amino acid are illustrated in FIG. 1.

The Zwitterion form (FIG. 1, denoted as “2” on the right panel) shows the local bonding situation where a proton can be attracted (NH₃⁺) and lost (CO₂⁻). There will be two channels (or two types of local off-diagonal moments) present for each amino acid molecule in an aqueous solution. A third channel, the protonic exciton state where the proton makes an intra-molecule hopping directly from COOH to NH2 is feasible.

Using the carboxyl site in the amino acid as an example, the two coherent eigenstates of the local hydrogen bond (FIG. 2) can be expressed as:

$$( \begin{matrix}α \vert COOH 〉 \vert {H}_{2} O 〉 + β \vert {COO}^{-} 〉 \vert {H}_{3} {O}^{+} 〉 \\ β \vert COOH 〉 \vert {H}_{2} O 〉 - α \vert {COO}^{-} 〉 \vert {H}_{3} {O}^{+} 〉\end{matrix} ) , {\vert α \vert}^{2} + {\vert β \vert}^{2} = 1 \qquad ( 4 )$$

which is schematically illustrated in FIG. 2.

For water molecules, there will be a local quantum coherent superposition of neutral H₂O and OH⁻, or H₃O⁺, albeit the orders of magnitude are smaller than those of amino acids. However, as a medium for virtual exchange of protons between Zwitterions, and as a reservoir to keep pH balance, water is critical in establishing the long range coherence of the off-diagonal moments of the amino acid molecules (defined as the coherent mixing amplitude between neutral amino acid molecular form and its Zwitterion form). Virtual exchange as used herein means indirect exchange through a medium such as water.

Another way to consider the role of the water environment is that it screens out the diagonal classical electric dipolar interaction between the local 2-level dipole and its environment, while on the other hand, reinforcing the quantum entanglement of the hydrogen bond. A complete screening of the diagonal moment corresponds to E₁=E₂, when the off-diagonal moment is the largest and the combined system becomes an anti-ferroelectric singlet.

It is known that having a stable local moment is far from sufficient to be used as qubits, as a single local moment as described above may quickly decohere. On the other hand, if long-range quantum coherence amongst these local off-diagonal moments can be achieved, the decoherence time can be exponentially longer with the number of such local moments achieve resonance/coherence.

The method and system for detecting and controlling long-range quantum coherence as disclosed herein is further explained in comparison to the Nuclear Magnetic Resonance. In NMR, for the local moments to achieve the long range order, a low temperature (^{˜}1 Kelvin or lower) and/or a large external magnetic field needs to be applied due to the weak hyperfine interaction between nuclear and electron spins. In NMR, the hyperfine interaction between nuclear and electron spins is highly sensitive to the thermal fluctuations in electronic degree of freedom, the latter (the electronic degree of freedom) again is coupled with thermal vibrations of the molecules in the system. In the system as disclosed herein, the spontaneous long range off-diagonal ordering of these local quantum electric dipole moments are self-reinforced by the chiral symmetry of the lowered energy state, determined by the pH level of the water environment, or the doping level of proton in condensed matter physics terms. The pH level of the water will select the spinning direction for all quantum moments in the two eigenstates. In other words, the doping of hydrogen is like the external field as illustrated in FIG. 2. This long range off-diagonal ordering, phase space spontaneous topological order in nature, will not be destroyed by the diagonal electric dipole coupling to the thermal vibrations of the water molecules and/or the amino acid molecules. This quantum topological nature of these off-diagonal moments is key to the method and system disclosed herein for room temperature quantum coherence.

To summarize, using hydrogen bond as an example, the nature of hydrogen bond amongst water molecules and between a water molecule and a biomolecule is due to coherent quantum coupling as shown in Equation (1), resulting in off-diagonal quantum moments, in addition to its classical diagonal electric dipole moment. These off-diagonal moments have the following unique properties:
Channel specific energy level splitting: for each local hydrogen bonding type, e.g., COOH or NH₂ in an amino acid, they are different in the bi-level splitting energy, thus resulting in different resonant frequencies for long range coherence of the excitations. The energy splitting \sqrt{(E₂−E₁)²+4Δ²}, can be controlled by the effective off-diagonal proton hopping amplitude Δ and the diagonal energy difference E₂−E₁, the latter of which can be controlled by proton doping level. The off-diagonal hopping amplitude is insensitive to the diagonal energy split and only depends on the local hydrogen bond characteristics.
Channel specific polarization controlled by the proton doping level: the two eigenstates have different chirality (dipole moment spinning direction), thus photo-absorption and photo-emissions will display strong dichroic behavior, which is an important feature in our experimental detection of these quantum moments.

### SUMMARY OF THE DISCLOSURE

The present disclosure relates to the discovery of electrical resonances of molecules such as water or biomolecules in an aqueous solution, in particular in the low end of radio frequency range at wide temperature ranges around room temperature (see, e.g., FIG. 7). In some embodiments, the electrical resonances are sharp signals. In some embodiments, the resonance has a half width at around and/or less than 0.5 MHz, indicating that the lifetime of the resonant excitation to be in the order of milliseconds. This long lifetime of the observed resonance cannot be explained by existing molecular theory of the dielectric properties of water, indicating that a macroscopic long range coherent quantum mechanical excited state is responsible for the resonance.

In one aspect, the present disclosure provides a method for detecting long-range quantum coherence of an interaction of molecules, comprising:
generating an electrical current of varying frequencies or generating electromagnetic fields of varying frequencies;
sending the electrical current or deploying the electromagnetic fields,
receiving an electrical or electromagnetic signal,
applying the signal to a test subject,
collecting responses from the test subject, and
analyzing the response.

In one embodiment, the interaction of the molecules comprises hydrogen bonds formed by exchange proton, a fermion. In one embodiment, the test subject comprises water or molecules, such as biomolecules, in an aqueous solution that form hydrogen bonds. In one embodiment, the test subject comprises a nature subject such as virus, biological cells, tissues, and/or organs. In one embodiment, the method is conducted at low to room temperature, such as from about −32° C. to about 55° C. For example, the method can be conducted at temperature from about −15° C. to about 50° C., from about −10° C. to about 45° C., from about −5° C. to about 40° C., from about 0° C. to about 35° C., from about 5° C. to about 30° C., or from about 10° C. to about 25° C. In one embodiment, the method is conducted at or around room temperature such as from 18 to 25° C. In one embodiment, the method is conducted at low AC to low end of radio frequency in the range from about 10 Hz to about 100 MHz. For example, the radio frequency is from 30 Hz to 300 GHz. In one embodiment, the pH of the test subject is from about 5 to about 8, from about 5 to about 7, or from about 6 to about 7. For example, the pH of the test subject is from about 6 to about 7. In one embodiment, the method is conducted at a bias voltage from about 0 to about 6 V. Bias voltage is a control parameter and can vary within a wide range depending on the applications. For example, the bias voltage is about 1.5 v. In one embodiment, the responses comprise a sharp electrical resonance signal. In one embodiment, the electrical resonance signal has a half width of less than 0.5 MHz. In one embodiment, the lifetime of the resonant excitation corresponding to the electrical resonance signal is in the order of milliseconds.

In another aspect, the present disclosure provides a system for detecting long-range quantum coherence of an interaction of molecules, comprising:
a device generating an electrical current of varying frequencies or generating electromagnetic fields of varying frequencies;
a device sending the electrical current or deploying the electromagnetic fields,
a device receiving an electrical or electromagnetic signal,
a device applying the signal to a test subject,
a device collecting responses from the test subject, and
a measuring device analyzing the responses.

The detected long range quantum coherence may be used as qubits, thus providing a hardware foundation for quantum memory chip and quantum computers.

The couplings between the resonance at different frequencies and the ability to manipulate the resonant frequency as well as the resonant magnitude, also provide a way to enhance or disrupt the established long range coherence, and may be used for medical applications, such as non-intrusive cancer treatments.

### BRIEF DESCRIPTION OF THE DRAWINGS

FIG. 1 illustrates an amino acid in neutral molecular form (left) and Zwitterion form (right). Source: https://en.wikipedia.org/wiki/Amino_acid#/media/File:Amino_acid_zwitterions.svg.

FIG. 2 shows an example of a channel in an amino acid originated from proton hoping (exchange). Note that a complete screening refers to no net electric dipole moment while incomplete screening results in a net electric dipole moment for the local hydrogen bond.

FIG. 3 illustrates a system for detecting and controlling long-range quantum coherence of an interaction of molecules, according to an embodiment.

FIG. 4A illustrates a system for detecting and controlling long-range quantum coherence of an interaction of molecules, according to an exemplary implementation of the embodiment illustrated in FIG. 3.

FIG. 4B illustrates a system for detecting and controlling long-range quantum coherence of an interaction of molecules, according to another exemplary implementation of the embodiment illustrated in FIG. 3.

FIG. 5A (upper panel) is the full spectrum of voltage vs frequency in distilled water wherein air data is plotted as dashed lines for comparison. FIG. 5B (lower panel) is the zoomed-in view of the peak at 34.27 MHz. The lifetime of the resonance is estimated to be ^{˜}1/(0.4 MHz), i.e. 2.5 millisecond.

FIG. 6 illustrates that resonant frequency becomes lower as inter-plate distance shortens.

FIG. 7A illustrates shows the sharpest resonant frequency vs temperature and pH, starting with a sharp high frequency peak at high temperature, ending with a sharp peak at lower frequency. FIG. 7B illustrates lower peak position vs temperature. FIG. 7C illustrates lower peak position vs pH.

FIG. 8 illustrates the lowest lying curve (Sweep 1) is the first sweep which corresponds to lowest ice temperature where no resonance features are observed. Sweep 2 (long dashed line) shows some high frequency resonances start to form. The low frequency feature starts to sharpen at sweep 5 (dotted line), and gradually moves lower to 32.26 MHz but comes back up to 32.87 MHz at the last two sweeps (Sweep 22 and Sweep 23). The right panel of FIG. 8 is a zoomed-in view of the left panel of FIG. 8.

FIG. 9A illustrates resonant frequency versus bias DC voltage. FIG. 9B illustrates that at bias DC voltage 1.5V, the resonant frequency oscillates over time and slowly stabilizes.

FIG. 10A illustrates three different sample 1 voltage (4 mV, 40 mV, 400 mV) results showing the full spectrum, and FIG. 10B shows the zoomed-in view around 32.26 MHz, the fixed frequency of the second generator.

FIG. 11 illustrates a comparison of resonance magnitude between distilled water (dashed line) and a fully saturated L-Tryptophan amino-acid solution.

FIG. 12 illustrates a system for detecting and controlling long-range quantum coherence of an interaction of molecules, according to still another exemplary implementation of the embodiment illustrated in FIG. 3.

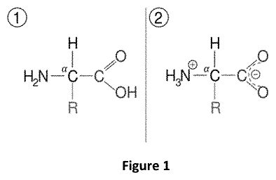

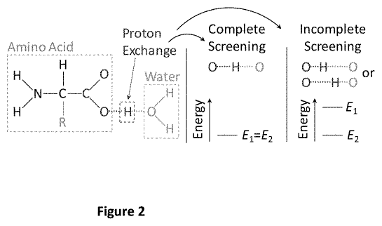

### DETAILED DESCRIPTION

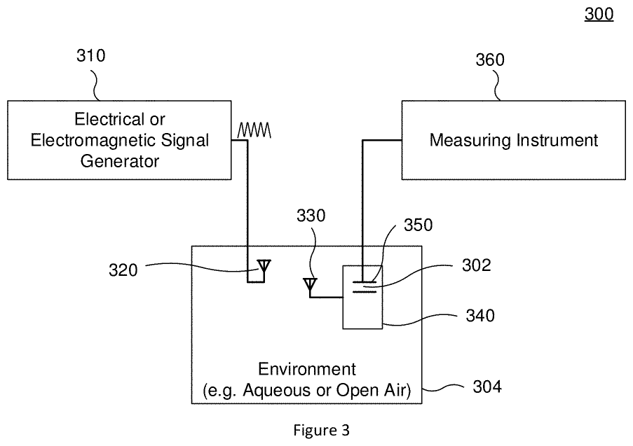

In one embodiment, FIG. 3 is a schematic diagram of a system 300 for detecting and controlling the long-range quantum coherence of molecular interactions such as hydrogen bonds, according to an embodiment. As illustrated in FIG. 3, the system 300 comprises a device 310 generating an electrical current of varying frequencies or generating electromagnetic fields of varying frequencies, a device 320 sending the electrical current or deploying the electromagnetic fields, a device 330 receiving an electrical or electromagnetic signal, a device 340 applying the signal to a test subject 302, a device 350 collecting responses from the test subject 302, and a measuring device 360 analyzing the responses. The test subject 302 comprises of water or molecules, e.g., biomolecules, that form hydrogen bonds, in an aqueous solution (e.g., water) disposed in a container 304.

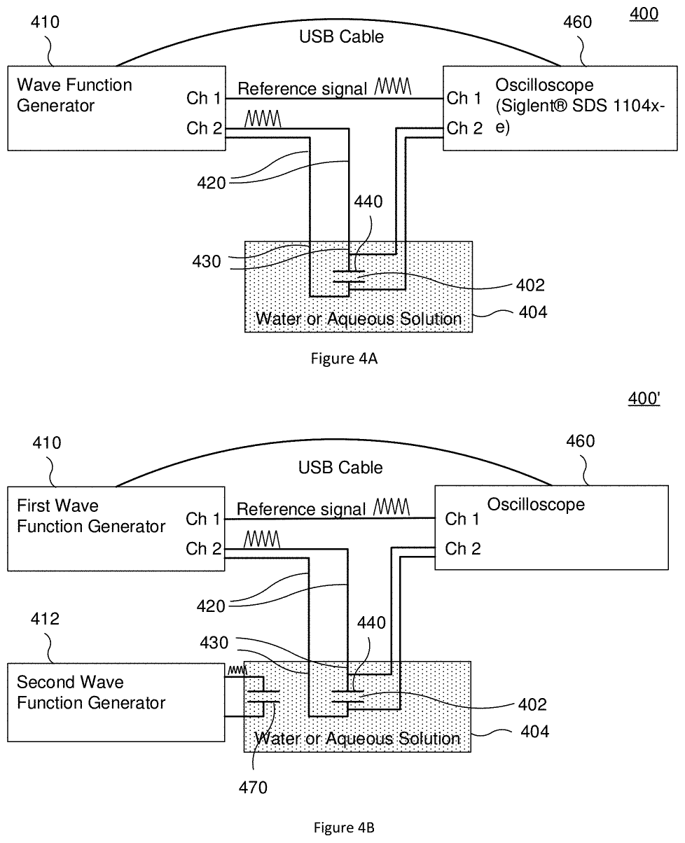

FIG. 4A illustrates a system 400 for detecting and controlling the long-range quantum coherence of molecular interactions, according to an exemplary implementation of the embodiment illustrated in FIG. 3. In the system 400 illustrated in FIG. 4A, the device generating the electrical current or electromagnetic fields may be a waveform function generator 410.

FIG. 4B illustrates a system 400′ for detecting and controlling the long-range quantum coherence of molecular interactions, according to another exemplary implementation of the embodiment illustrated in FIG. 3. In the system 400′ illustrated in FIG. 4B, the device generating the electrical current or electromagnetic fields may be first and second waveform function generators 410 and 412. In some examples, first and second waveform function generators 410 and 412 may be Siglent® SDG2122x and Siglent® SDG2042x. The first and second waveform function generators 410 and 412 may also be other instruments, such as impedance analyzer, spectrum analyzer, network analyzer, vector network analyzer, nano vector network analyzer.

In the embodiments illustrated in FIGS. 4A and 4B, the device sending the electrical current or deploying the electromagnetic fields and the device receiving the electrical or electromagnetic signal may be conductive lines 420 and 430 connected between electrodes (labeled as “Ch 2”) of wave function generator 410 in open air and in water. Specifically, the device sending the electrical current or deploying the electromagnetic fields, and the device receiving the signal, may include sections of the conductive lines 420 in open air and sections of the conductive lines 430 in water. In some other applications, such as the embodiment illustrated in FIG. 3, the device 320 sending the electrical current or deploying the electromagnetic fields and the device 330 receiving the electrical or electromagnetic signal may also be large sized underwater antenna and/or underwater radio frequency signal relay towers.

In the embodiments illustrated in FIGS. 4A and 4B, the device applying the signal to a test subject and the device collecting the responses from the test subject may be a pair of parallel conductive plates 440, acting as capacitor with water or aqueous solution between the plates. In some examples, the device applying the signal to a test subject and the device collecting the responses from the subject are a pair of parallel gold-plated or silver-plated metal plates 440, separated to allow water or aqueous solution filled in-between the plates. In other embodiments, such as the embodiment illustrated in FIG. 3, the device 340 applying the signal to the test subject 302 and the device 350 collecting the responses from the test subject 302 can be separate devices. For example, as illustrated in FIG. 3, the device 350 collecting the responses may be a pair of parallel conductive plates, and the device 340 applying the signal may be other devices such as another pair of parallel conductive plates. In another embodiment (not illustrated), the device 340 applying the signal may be a second pair of parallel conductive plates, and the conductive plates (first pair of conductive plates) of the device 350 collecting the responses are disposed between the conductive plates (second pair of conductive plates) of the device 340 applying the signal. The device collecting the response from the test subject may be part of the measuring device described below.

In the embodiments illustrated in FIGS. 4A and 4B, the measuring device may be an oscilloscope 460. In some examples, the oscilloscope 460 may be Siglent® SDS1104x-e. The measuring device 460 may also be any other measuring instrument capable of measuring the transmissive, reflective, and/or refractive responses of these signals at varying frequencies, such as impedance analyzer, spectrum analyzer, network analyzer, vector network analyzer, nano vector network analyzer, dichroic spectrometer. The measuring device may send separate probing signal to the test subject and collect the response of the probing signal.

FIGS. 4A and 4B show a USB cable and a separate cable connecting the wave function generator 410 and the oscilloscope 460 for transmitting reference signals between the wave function generator 410 and oscilloscope 460 (labeled as “Ch 1”), which facilitate automatically generating bode plots and recording corresponding data in the oscilloscope.

In one embodiment, the method for detecting and controlling the long-range quantum coherence of molecular interactions, such as hydrogen bonds may be implemented as follows.

For example, a user may construct a test subject or present an existing test subject that contain water or aqueous solution with molecules that form hydrogen bonds. The test subject can be water or aqueous solution 402 disposed in the container 404 as illustrated in FIG. 4A or 4B, or can be a nature subject (for example, virus, biological cells, tissues, and/or organs) that includes an aqueous environment within which biomolecules forming hydrogen bonds.

The temperature and PH level of the water or aqueous solution may be measured and recorded. Temperature and PH level are important because the resonant frequencies vary with many factors including these two parameters.

An instrument may be used to generate an electrical current or electromagnetic fields of varying frequencies (e.g., below 1 GHz). For example, in FIG. 4A, the waveform generator 410 is used to generate sine-wave electrical signals from 10 Hz to 100 MHz.

A device sending the electrical current or electromagnetic fields and a device receiving the electrical current or electromagnetic fields may be configured between the device generating electrical current or electromagnetic fields and the device applying the electrical current or electromagnetic fields to the test subject. The configuration of the device sending the electrical current or electromagnetic fields and the device receiving the electrical current or electromagnetic fields may vary depending on a number of the factors, such as the distance between the signal generating device and the test subject, the nature of the subject, etc. In FIGS. 4A and 4B, the device sending the electrical current or electromagnetic fields and the device receiving the electrical current or electromagnetic fields comprise conductive lines 420 and 430. In some other applications, as illustrated in FIG. 3, the device sending the electrical current or electromagnetic fields and the device receiving the electrical current or electromagnetic fields can comprise complex components such as high-power antenna 320 and 330.

In one embodiment, a device is configured to apply the electrical current or electromagnetic fields to the water or aqueous solution, and a device is configured to collect the response of the water or aqueous solution subject to the water or aqueous solution at various frequencies. The configuration of the device applying the electrical current or electromagnetic fields and the device collecting the response depend on which physical properties of the hydrogen bonds the user wants to measure in order to detect the resonant response. For example, the resonant response may be detected through measuring the complex permittivity (or dielectric constant) of the water or aqueous solution at various electrical frequencies. In order to do so, in the embodiments illustrated in FIGS. 4A and 4B, the device applying the electrical current and the device collecting the response may be configured as a pair of parallel gold-plated metal plates 440, separated by a thin layer of the insulator such as plastic on both ends of the plates to allow air or water filled in-between the plates. The pair of parallel gold-plated metal plates 440 acts as capacitor. As electrical currents at varying frequencies are applied to the plates, the amplitude and the phase of the signal responses from the parallel plates are passed to the measuring device.

The transmissive, reflective, and/or refractive responses of these signals may be measured at varying frequencies using a measuring device. The type of the measuring device may depend on what aspects of the response signal the user wants to measure. For example, in the embodiments illustrated in FIGS. 4A and 4B, the oscilloscope 460 may be used to measure the amplitude and phase of the response signals at varying electrical frequencies. Note that there can be multiple types of measuring devices that can measure the same physical properties. For example, instead of the oscilloscope, the complex permittivity of the water can also be measured using impedance analyzer, spectrum analyzer, network analyzer, vector network analyzer, nano vector network analyzer, etc. In some examples, some measuring methods or measuring devices may send separate signals to the test subject and collect responses of those signals.

The resonant frequencies may be identified from the response profile at varying frequencies. For example, when hydrogen bonds are at resonant frequencies, the permittivity of the water or aqueous solution will increase dramatically, evidenced by a sharp spike in the amplitude of the electrical response signal and a corresponding shift in phase. Also for example, the Bode Plot of the parallel plates in open air and in distilled water may be compared to identify a sharp increase in amplitude of the signal response and corresponding phase shift at frequencies in the order of tens of MHz, which is the resonant frequency, with the resonance lifetime in the order of microseconds as imputed from the half width of the resonance.

In some examples, the resonant frequency, as well as observed response (for example, resonant lifetime, amplitude of the response signal) is sensitive to and can vary with a number of factors, including material and construct of the device applying the signal (for example, the distance between two plates 440 in FIGS. 4A and 4B), temperature and structural ordering/phase of the water or aqueous solution, pH level of the water or aqueous solution, bias DC voltage in the signal, presence of interfering/coupling signals, and molecules in the aqueous solution forming the hydrogen bonds, etc.

The long-range quantum coherence of hydrogen bonds may be controlled. For example, through detecting the resonant frequencies of the hydrogen bonds on the test subject, the long-range quantum coherence can be established by applying the electric current or electromagnetic fields at the resonant frequencies to the subject. Also for example, the resonant frequencies of a test subject can be altered by altering a number of factors, including material and configuration of the device applying the signal (for example, the distance between two plates 440 in FIGS. 4A and 4B), temperature and structural ordering/phase of the water or aqueous solution, pH level of the water or aqueous solution, bias DC voltage in the signal, presence of interfering/coupling signals, and molecules in the aqueous solution forming the hydrogen bonds.

Using the above described system and method, a sharp electrical resonance of water in the low end of radio frequency range is observed at room temperature in an experiment. In the experiment, the sharpest resonance has a half width less than 0.5 MHz, indicating that the lifetime of the resonant excitation to be in the order of milliseconds. This long lifetime of the observed resonance which cannot be explained by existing molecular theory of the dielectric properties of water, strongly suggests that a macroscopic long range coherent quantum mechanical excited state is responsible for the resonance.

The following examples are provided to describe the disclosure in greater detail. They are intended to illustrate, not to limit, the disclosure.

Experiment results are described below regarding the sharp resonance observed for distilled water. The sensitivity of the resonance on bias voltage, pH level (proton doping), temperature, structural ordering, and other boundary conditions are discussed. It is noted that L-Tryptophan (an amino acid) water solution show greatly enhanced resonance amplitude and much narrower width than the distilled water.

### Example 1. Resonance in Distilled Water

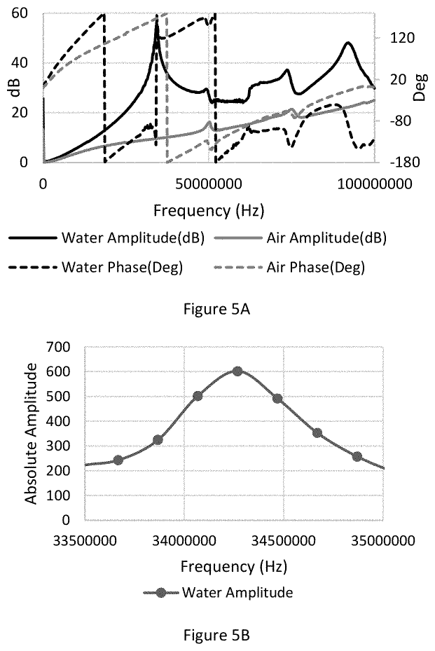

To establish a baseline profile, the test subject's amplitude and phase responses to electrical frequencies are measured in open air (“Open Air”, dashed lines in FIG. 5A). The test subject is then submerged in distilled water. Frequency responses are again recorded (solid lines in FIG. 5A, “Distilled Water”). Compared to the “Open Air” baseline, a sharp ramp-up of amplitude, peaking around 34.27 MHz, is observed. An abrupt change in phase is also observed neighboring that frequency.

In addition to the sharp resonance observed at 34.27 MHz, small spikes at higher frequencies around 50 MHz, 72 MHz, and 92 MHz, with 50 and 72 MHz are also observed in air sample.

The sharp changes in the amplitude and the phase point to a change in the permittivity of water caused by a resonant response of water around the resonant frequency. Resonant response of water in this low frequency range has not been documented before, and cannot be explained by any existing theory.

### Example 2. Sensitivities of the Resonance on Various Environment/Sample Factors

The sharp resonant feature observed can be very sensitive to the sample geometric characteristics, for example, the distance between the two plates. In addition, the resonant feature observed is also sensitive to various parameters: sample material, temperature of the water, pH level of the water, bias DC voltage across the metallic plates, and most significantly, amino acid solvent in water seems to greatly enhance the resonant signal toward much longer resonant lifetime and higher dielectric response amplitude.

### Example 3. Sensitivity on Inter-Plate Distance

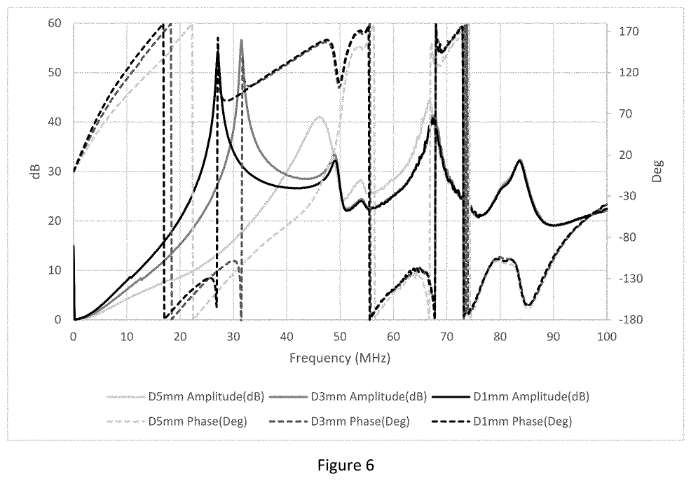

For the two gold plate samples (rectangular ^{˜}5 mm×25 mm), the sharpest resonant frequency may shift lower with lower inter-plate distance. This observation (see FIG. 6) qualitatively by using two larger (^{˜}20 mm diameter circular plate) and adjust the inter-plate distance hanging from a plastic string without any GLAD Wrap bound.

In addition, the higher frequency features are more stable than the sharpest resonance. This frequency dependence on inter-plate distance may not be attributed to higher field strength of the applied (zero DC bias) electric field, because for a wide range of applied voltage (0.004 V to 4 V), the in-situ resonant frequency does not change.

### Example 4. Sensitivity on pH and Temperature

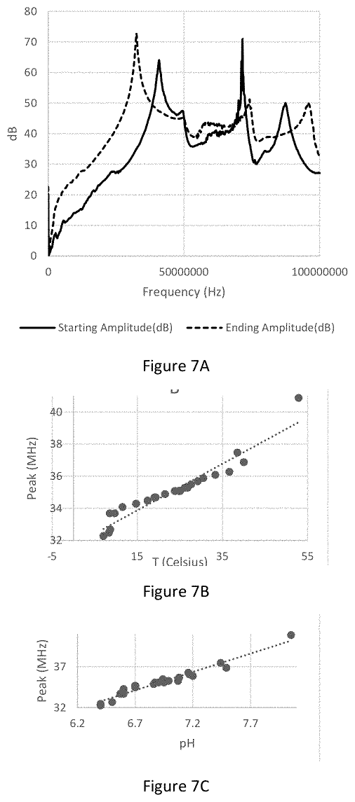

The distilled water under temperature around 20° C. has a pH value ^{˜}5.6 and it is due to the carbon dioxide solvent in water. In order to change the pH for pure water, the distilled water and measurements of the Bode Plot for each sweep are taken. At the start of the measurement, the temperature of the water is 79° C. with pH at 6.9. At the end of each sweep/scan of the Bode Plot, there are the two sharpest resonant frequencies and corresponding amplitudes, in addition to the pH value and the temperature of the water. FIGS. 7A-7C show the sharpest resonant frequency vs temperature and pH.

It may be difficult to separate the impact of temperature and pH from the results as there is a strong collinearity between the pH and temperature.

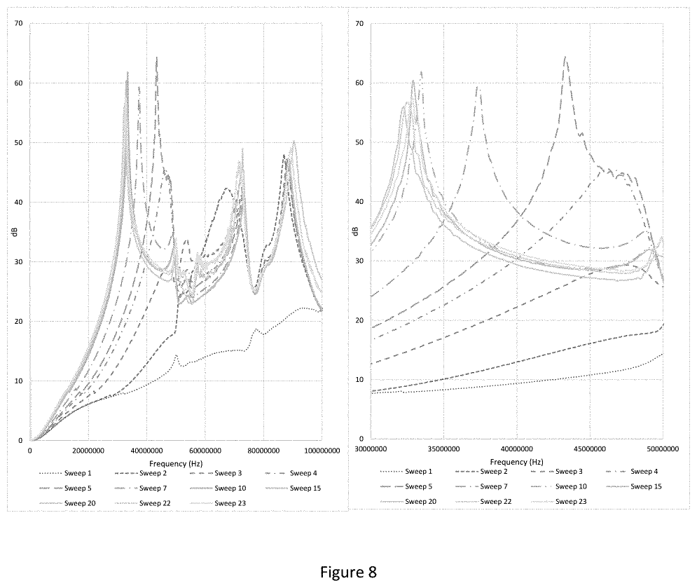

In order to probe the temperature dependence below or around the freezing temperature, the same sample is frozen in freezer set at −32° C. The Bode Plot is started after the sample is taken out of the freezer. The pH and water temperature are measured after the last sweep of data taken and their respective values are 6.5 for pH and 8.1° C. for temperature. No resonance is observed at first sweep (see FIG. 8), and it starts to appear at higher frequency. As the sample starts to warm up, the peak starts to sharpen and peak frequency drifts from ^{˜}43 MHz to 32.26 MHz at the last sweep. This suggests a different temperature dependence at lower temperature than at higher temperature. One of ordinary skill in the art will understand that inter-molecular distance of water is the smallest at around 4° C., the change of temperature dependence for the resonant frequency may coincide with the change of thermal expansion coefficient of water. Around freezing temperature, a first order structural phase transition also kicks in and the experimental results may not conclusively separate all these factors (temperature, pH, and structural ordering) on the resonant feature observed. Resonant feature start to stabilize after Sweep 10 where ice melting at the contact with the metallic plates can be seen.

### Example 5. Sensitivity on Bias DC Voltage

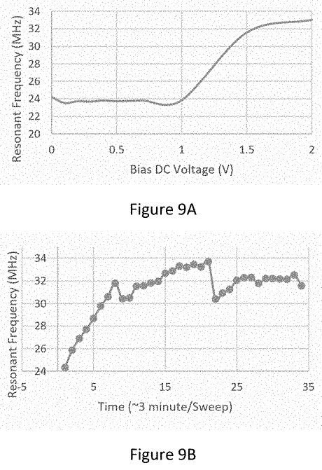

When the bias is changed during the course of this experiment, it may take a long time for the Bode Plot data to stabilize, sometimes as long as over two hours, as DC bias mainly tries to align the micro domains of water molecules responsible for the resonance. FIG. 9A shows the stabilized resonant frequency versus bias DC voltage and FIG. 9B shows at Bias Voltage at 1.5V, the resonant frequency oscillates over time.

### Example 6. Observation of Resonant Response from Second Signal Generator

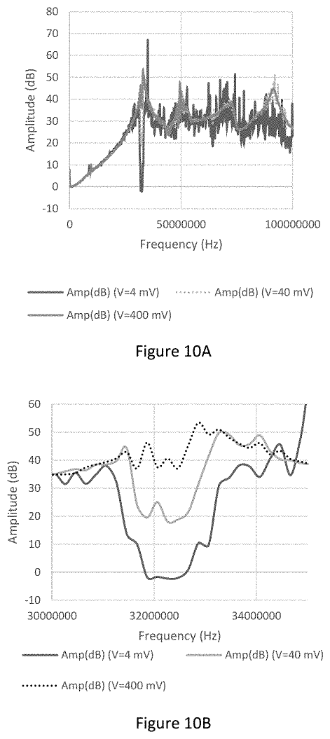

As shown in FIG. 4B, a pair of second metallic plates 470 is put in the water and is connected only to the second signal generator 412. The signal collected for sample 1 (the pair of metallic plates 440) will reflect the cross talk effect due to the second signal generator 412. The second signal generator 412 is at a fixed frequency of 32.26 MHz, which is the resonant frequency of the sample 1 before we put sample 2 (the pair of second metallic plates 470) in the water. The sample 2 voltage is set at 4V, and we change the sample 1 voltages at 4 mV, 40 mV, and 400 mV. FIGS. 10A and 10B show the three different sample 1 voltage results with FIG. 10A showing the full spectrum, and FIG. 10B showing the zoomed-in view around 32.26 MHz. The impact of crosstalk from the second signal is evident and it depends on the relative amplitude between the two signals, as expected. Except for more noises in the data, the resonant frequency of the original sample 1 does not change with the voltage applied on itself. The cross talk is present when the two plates are perpendicular to each other, as well as other relative orientations.

### Example 7. Observation of Resonant Response from Second Signal Generator

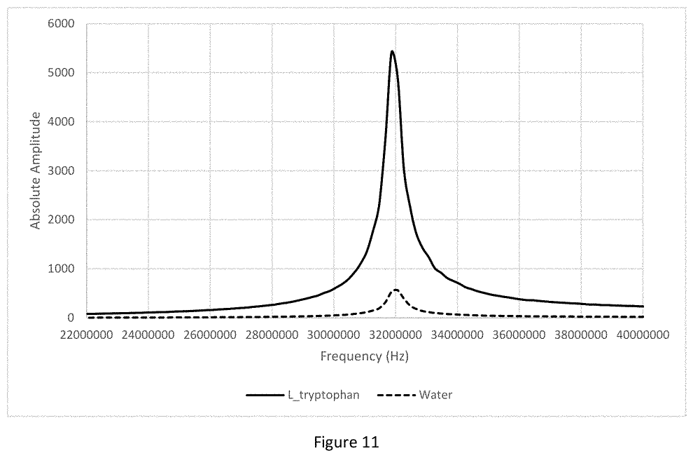

It is noted that some amino acid molecules have dramatic impact on the amplitude at the resonant frequency, even though the pH value does not seem to differ very much. The water solution is stirred fully until the amino-acid molecules reaches its maximum solubility. FIG. 11 shows the comparison between distilled water and fully saturated L-Tryptophan (purity >99%) water solution. The amplitude in (10 dB/20) is plotted to show the dramatic increase of the resonance magnitude.

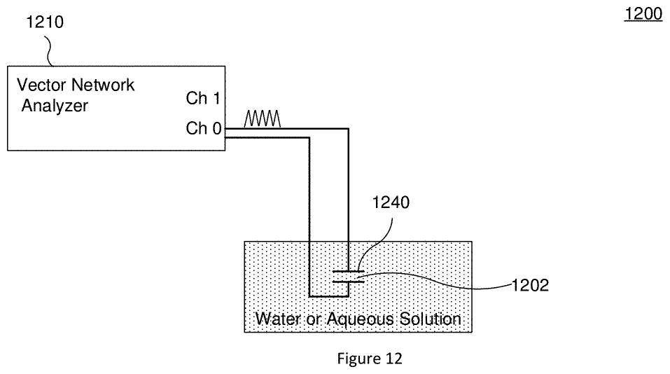

FIG. 12 illustrates a system for detecting and controlling long-range quantum coherence of an interaction of molecules, according to still another exemplary implementation of the embodiment illustrated in FIG. 3. As illustrated in FIG. 12, a vector network analyzer 1210 generates electric signals at low radio frequency range and measures the impedance at varying frequencies of the test subject 1202 which is composed of water or aqueous solution disposed between a pair of parallel conductive plates 1240, acting as a capacitor. The vector network analyzer 1210 may be a NanoVNA® vector network analyzer. In this setup of measurement of impedance, the resonance peak would correspond to a dip in real part of the impedance.

While illustrative embodiments have been described herein, the scope of the present disclosure covers any and all embodiments having equivalent elements, modifications, omissions, combinations (e.g., of aspects across various embodiments), adaptations and/or alterations as would be appreciated by those skilled in the art based on the present disclosure. For example, features included in different embodiments shown in different figures may be combined. The limitations in the claims are to be interpreted broadly based on the language employed in the claims and not limited to examples described in the present specification or during the prosecution of the application. The examples are to be construed as non-exclusive. It is intended, therefore, that the specification and examples be considered as illustrative only, with a true scope and spirit being indicated by the following claims and their full scope of equivalents.

1. A system for detecting and controlling long-range quantum coherence of an interaction of molecules, comprising:
a device generating an electrical current of varying frequencies or generating electromagnetic fields of varying frequencies;
a device sending the electrical current or deploying the electromagnetic fields,
a device receiving an electrical or electromagnetic signal,
a device applying the signal to a test subject,
a device collecting responses from the test subject, and
a measuring device analyzing the responses.

2. The system of claim 1, wherein the interaction of the molecules comprises hydrogen bonds.

3. The system of claim 1, wherein the test subject comprises water or molecules in an aqueous solution that form hydrogen bonds.

4. The system of claim 1, wherein the test subject comprises a nature subject.

5. The system of claim 1, wherein the device sending the electrical current or deploying the electromagnetic fields and the device receiving an electrical or electromagnetic signal are conductive lines.

6. The system of claim 1, wherein the device applying the signal to the test subject and the device collecting responses from the test subject are a pair of parallel conductive plates.

7. A method for detecting and controlling long-range quantum coherence of an interaction of molecules, comprising:
generating an electrical current of varying frequencies or generating electromagnetic fields of varying frequencies;
sending the electrical current or deploying the electromagnetic fields,
receiving an electrical or electromagnetic signal,
applying the signal to a test subject,
collecting responses from the test subject, and
analyzing the responses.

8. The method of claim 7, wherein the test subject comprises water or molecules in an aqueous solution that form hydrogen bonds.

9. The method of claim 7, wherein the test subject comprises a nature subject.

10. The method of claim 7, wherein the method is conducted at low to room temperature.

11. The method of claim 7, wherein the method is conducted at low end of radio frequency range.

12. The method of claim 7, wherein pH of the test subject is from about 5 to about 7.

13. The method of claim 7, wherein the method is conducted at a bias voltage from about 0 to about 6 v.

14. The method of claim 10, wherein the method is conducted at low to room temperature.

15. The method of claim 14, wherein the responses comprise a sharp electrical resonance signal.

16. The method of claim 15, wherein the electrical resonance signal has a half width of less than 0.5 MHz.

17. The method of claim 16, wherein the lifetime of the resonant excitation corresponding to the electrical resonance signal is in the order of milliseconds.

18. The method of claim 12, wherein the pH of the test subject is from about 6 to about 7.

19. The method of claim 13, wherein the method is conducted at a bias voltage of about 1.5 v.

20. The method of claim 14, wherein the method is conducted at from about −32° C. to about 55° C.
